(19) United States
(12) Patent Application Publication
(10) Pub. No.: US 2026/0121139 A1
(43) Pub. Date: Apr. 30, 2026

(54) CHARGING METHOD, AND MOBILE TERMINAL

(71) Applicant: REALME MOBILE TELECOMMUNICATIONS (SHENZHEN) CO., LTD., Shenzhen (CN)

(72) Inventors: Huanran TANG, Shenzhen (CN); Jianglong XIE, Shenzhen (CN); Zejin YANG, Shenzhen (CN)

(21) Appl. No.: 19/431,104

(22) Filed: Dec. 23, 2025

Related U.S. Application Data
(63) Continuation of application No. PCT/CN2024/140697, filed on Dec. 19, 2024.

(30) Foreign Application Priority Data
Dec. 29, 2023 (CN) 202311862854.6

(51) Int. Cl. H01M 10/44; G01R 31/367; G01R 31/3828; G01R 31/3842; G01R 31/389; G01R 31/392; G01R 31/396

(52) U.S. Cl. CPC H01M 10/443; G01R 31/367; G01R 31/3828; G01R 31/3842; G01R 31/389; G01R 31/392; G01R 31/396

(57) ABSTRACT

Provided are a charging method, a mobile terminal and a computer-readable storage medium. The method includes operations as follows. Battery aging information is acquired in a case where a battery meets a preset trigger condition, where the preset trigger condition includes a trigger condition for switching from a constant current charging mode to a constant voltage charging mode. Charging is stopped for a preset duration, in a case where it is determined the battery aging information meets a charging acceleration condition. A voltage drop of the battery is obtained based on a voltage of the battery before stopping the charging and a voltage of the battery after stopping the charging, and the battery is charged based on the voltage drop.

### CROSS-REFERENCE OF RELATED APPLICATIONS

This application is a continuation of International Application No. PCT/CN2024/140697 filed Dec. 19, 2024, which claims priority to Chinese Patent Application No. 202311862854.6, filed Dec. 29, 2023, the entire disclosures of which are incorporated herein by reference.

### TECHNICAL FIELD

The disclosure relates to the field of charging technologies, and in particular to a charging method, a mobile terminal and a non-transitory storage medium.

### BACKGROUND

With the development of mobile communication technologies, mobile terminals such as mobile phones and tablet computers have become widespread, which brings great convenience to people's daily lives and work. Currently, the battery of the mobile terminal is generally charged based on a preset charging curve. However, as the mobile device is used over time, it is common for the battery charging speed to gradually slow down.

### SUMMARY

Embodiments of the disclosure provide a charging method, a mobile terminal, and a non-transitory storage medium.

In a first aspect, the embodiments of the disclosure provide a charging method, including:
acquiring battery aging information in a case where a battery meets a preset trigger condition during a process of charging the battery in a constant current charging mode, where the preset trigger condition includes a trigger condition for switching from the constant current charging mode to a constant voltage charging mode;
in a case where it is determined that the battery aging information meets a charging acceleration condition, stopping charging for a preset duration; and
acquiring a voltage drop of the battery based on a voltage of the battery before stopping the charging and a voltage of the battery after stopping the charging, and charging the battery based on the voltage drop.

In a second aspect, the embodiments of the disclosure provide a mobile terminal. The mobile terminal includes a memory and a processor. A computer program is stored in the memory, and the computer program, when being executed by the processor, cause the processor to execute operations of the charging method in the first aspect.

In a third aspect, the embodiments of the disclosure provide a non-transitory computer-readable storage medium having a computer program stored thereon. The computer program, when being executed by a processor, causes operations of the method in the first aspect to be implemented.

### BRIEF DESCRIPTION OF THE DRAWINGS

In order to more clearly illustrate technical solutions in the embodiments of the disclosure or the related art, drawings to be used in the embodiments or the related art are briefly described below. Apparently, the following drawings are merely some embodiments of the disclosure, and a person skilled in the art can obtain other drawings according to these drawings without paying any creative effort.

FIG. 1 is a schematic diagram illustrating an application environment to which a charging method according to some embodiments is applicable.

FIG. 2 is a flowchart of a charging method according to some embodiments.

FIG. 3 is a flowchart of a charging method according to some other embodiments.

FIG. 4 is a schematic flowchart of an operation of charging a battery based on a voltage drop according to some embodiments.

FIG. 5 is a schematic flowchart of an operation of charging a battery with a target charging current according to some embodiments.

FIG. 6 is a schematic flowchart of an operation of determining whether a battery meets a preset trigger condition according to some embodiments.

FIG. 7 is a flowchart of a charging method according to yet other embodiments.

FIG. 8 is a structural block diagram of a charging apparatus according to some embodiments.

FIG. 9 is an internal structural diagram of a mobile terminal according to some embodiments.

### DETAILED DESCRIPTION OF PREFERRED EMBODIMENTS

In order to make the objectives, technical solutions, and advantages of the disclosure more clearly, the disclosure will be further described in detail below with reference to the drawings and embodiments. It should be understood that the specific embodiments described herein are only used to explain the disclosure and are not intended to limit the disclosure.

With the development of mobile communication technologies, mobile terminals such as mobile phones and tablet computers have become widespread, which brings great convenience to people's daily lives and work. Currently, the battery of the mobile terminal is generally charged based on a preset charging curve. For example, a battery is first charged with a constant current of 1500 mA until the battery reaches 9.0V, then it is switched to constant voltage charging, and the charging ends when the current decreases to 250 mA. However, as the mobile device is used over time, battery aging occurs, and an internal resistance of the battery increases. Consequently, a battery voltage of the aging battery rises faster than that of a new battery when charged with the same current, so that the battery voltage of the aging battery more quickly reaches a switch voltage, thereby switching from the constant current charging mode to the constant voltage charging mode. The constant voltage charging mode requires a longer charging time for the aging battery than for the new battery, thereby causing a continual decrease in the charging speed as the battery ages.

In view of this, the embodiments of the disclosure provide a charging method. During a charging process of a battery, in a case where the battery meets a trigger condition for switching from a constant current charging mode to a constant voltage charging mode, battery aging information of the battery is acquired. In a case where it is determined, based on the battery aging information, that the battery is aged, it requires to take charging acceleration measures, that is, the charging is stopped for a preset duration, a voltage drop of the battery is obtained based on a voltage of the battery before stopping the charging and a voltage of the battery after stopping the charging, and then the battery is charged based on the voltage drop. Through the embodiments of the disclosure, the charging can be performed based on a state of the battery, and in particular, after the battery has aged, different charging measures are taken based on the aging degree of the battery. In this way, the decline in the charging speed of the aging battery is slowed down, which alleviates the problem of continual decrease in the charging speed.

The charging method according to the embodiments of the disclosure may be applied to an application environment illustrated in FIG. 1. The application environment includes a mobile terminal. The mobile terminal includes a battery 101, various sensors 102, and a processor 103. The processor 103 may acquire sensing data from the various sensors 102, and control charging and discharging of the battery 101. The mobile terminal 102 may include, but is not limited to, a laptop computer of various types, a smartphone, a tablet computer, a portable wearable device such as a smartwatch, a smart bracelet, and a head-mounted device, and etc. The battery 101 may include, but is not limited to, a lithium battery, a lithium iron phosphate battery, etc. The sensor 102 may include, but is not limited to, a temperature sensor, a voltage sensor, a current sensor, etc. The processor 103 may include, but is not limited to, various smart chips.

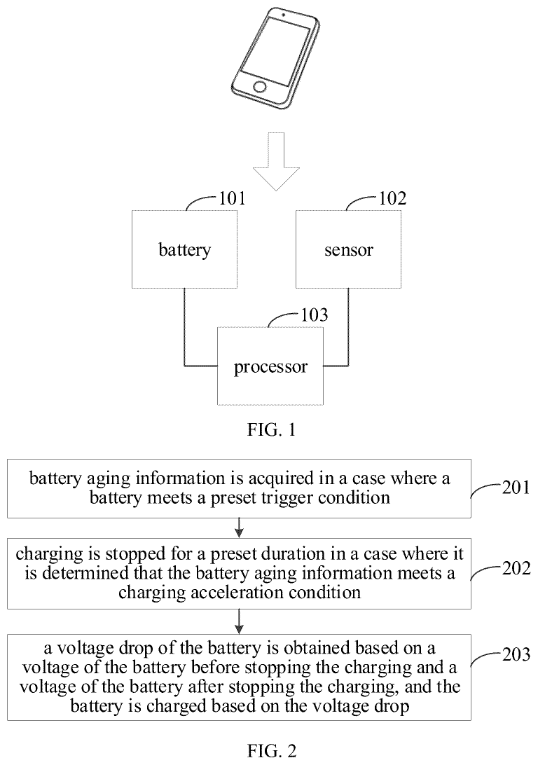

As illustrated in FIG. 2, a charging method is provided according to some embodiments. Taking the method applied to the mobile terminal in FIG. 1 as an example, the method includes operations 201, 202 and 203.

At operation 201, battery aging information is acquired in a case where a battery meets a preset trigger condition.

The preset trigger condition includes a trigger condition for switching from a constant current charging mode to a constant voltage charging mode. The trigger condition may be that a battery voltage reaches a preset voltage threshold, or a battery current reaches a preset current threshold, or a battery capacity reaches a preset capacity threshold. It is notable that the preset trigger condition is not limited to the above trigger conditions, and may be set according to actual conditions. For example, in a case where the battery capacity is greater than or equal to the preset capacity threshold, it is determined that the battery meets the preset trigger condition; in a case where the battery capacity is less than the preset capacity threshold, it is determined that the battery does not meet the preset trigger condition.

The battery aging information may include state of health (SOH) of the battery. The SOH may represent an energy storage capacity of a current battery relative to that of a new battery, and is expressed as a percentage to indicate a state of the battery from the beginning to the end of the life cycle.

During the charging process of a battery, the battery may be first charged based on a charging curve in Table 1.

TABLE 1

| Temperature | |
|---|---|
| Range | Charging Curve |
| −10° C.-0° C. | charge with a constant current of 0.3 C until reaching 9.0 V, and charge with a |
| | constant voltage until reaching 0.05 C |
| 0° C.-5° C. | charge with a constant current of 1.2 C until reaching 8.4 V, charge with a |
| | constant current of 1.0 C until reaching 9.0 V, charge with a constant current |
| | of 0.8 C until reaching 9.1 V, and charge with a constant voltage until reaching |
| | 0.13 C |
| 5° C.-10° C. | charge with a constant current of 1.5 C until reaching 8.4 V, charge with a |
| | constant current of 1.2 C until reaching 9.0 V, charge with a constant current |
| | of 0.8 C until reaching 9.1 V, and charge with a constant voltage until reaching |
| | 0.15 C |
| 10° C.-18° C. | charge with a constant current of 3.0 C until reaching 8.4 V, charge with a |
| | constant current of 2.0 C until reaching 9.0 V, charge with a constant current |
| | of 1.4 C until reaching 9.1 V, and charge with a constant voltage until reaching |
| | 0.1 C |
| 18° C.-35° C. | charge with a constant current of 4.5 C until reaching 8.5 V, charge with a |
| | constant current of 4.0 C until reaching 8.7 V, charge with a constant current |
| | of 3 C until reaching 9.0 V, charge with a constant current of 2 C until reaching |
| | 9.1 V, and charge with a constant voltage until reaching 0.3 C |
| 35° C.-45° C. | charge with a constant current of 4.5 C until reaching 8.5 V, charge with a |
| | constant current of 4.0 C until reaching 8.7 V, charge with a constant current |
| | of 3 C until reaching 9.0 V, charge with a constant current of 2 C until reaching |
| | 9.1 V, and charge with a constant voltage until reaching 0.5 C |
| 45° C.-55° C. | charge with a constant current of 0.6 C until reaching 8.3 V |

In Table 1, C represents a capacity of the battery. Taking a battery with a capacity C of 5000 mAh as an example, “charge with a constant current of 0.3C until reaching 9.0V, and charge with a constant voltage until reaching 0.05C” means: charging with a constant current of 0.3×5000-1500 mA until a voltage reaches 9.0V, followed by a constant voltage charging until a current is decreased to 250 mA, and then the charging ends.

The mobile terminal monitors a charging state of the battery, and acquires the battery aging information, for example, the state of health of the battery, when determining that the battery meets the preset trigger condition.

In some embodiments, there is a relationship between the state of health and an internal resistance of the battery, specifically, the worse the state of health of the battery (i.e., the lower the SOH value), the higher the internal resistance of the battery. Thus, the internal resistance of the battery may be calculated by measuring a voltage, a current, a temperature, etc. of the battery, and then the state of health of the battery may be calculated based on the calculated internal resistance of the battery and a pre-established correspondence relationship between the states of health and the internal resistances of the battery.

In some embodiments, the mobile terminal may calculate the state of health of the battery in real time, thereby acquiring the battery aging information. Alternatively, the state of health of the battery may be calculated according to a preset cycle and stored in a preset storage space. When it is determined that the battery meets the preset trigger condition, the state of health of the battery may be retrieved from the preset storage space, thereby acquiring the battery aging information.

It is notable that the implementations for acquiring the battery aging information is not limited to the above description, and may be set according to actual conditions.

At operation 202, charging is stopped for a preset duration, in a case where it is determined that the battery aging information meets a charging acceleration condition.

Specifically, the charging acceleration condition may include that the battery aging information indicates that an aging degree of the battery reaches a preset aging degree, or the state of health of the battery is lower than a preset health degree threshold.

After acquiring the battery aging information, it is determined whether the battery aging information meets the charging acceleration condition. When it is determined that the charging acceleration condition is met, the charging is stopped for the preset duration. For example, the charging is stopped for 20 seconds. It is notable that the preset duration is not limited to 20 seconds, and may be set according to actual conditions.

At operation 203, a voltage drop of the battery is obtained based on a voltage of the battery before stopping the charging and a voltage of the battery after stopping the charging, and the battery is charged based on the voltage drop.

A first battery voltage before stopping the charging and a second battery voltage after stopping the charging for the preset duration are acquired, and a voltage difference between the first battery voltage and the second battery voltage is calculated, thereby obtaining the voltage drop. For example, when the first battery voltage before stopping the charging is 9.0V and the second battery voltage after stopping the charging for the preset duration is 8.7V, the voltage drop may be determined as 0.3V.

It may be understood that the higher the aging degree of the battery, the greater the internal resistance of the battery and the greater the voltage drop. Thus, different charging measures may be taken according to different amplitudes of the voltage drop. For example, when the voltage drop is aV, the battery is charged with a charging current I1; when the voltage drop is bV, the battery is charged with a charging current I2; and when the voltage drop is cV, the battery is charged with a charging voltage U. That is to say, the voltage drop, i.e., a charging float voltage, accurately indicates the aging degree of the battery, which enables more precise matching of the charging current required by the battery, thereby maximizing the charging speed without compromising the battery life.

In the above embodiments, the battery aging information is acquired when the battery meets the preset trigger condition, the charging is stopped for the preset duration when it is determined that the battery aging information meets the charging acceleration condition, the voltage drop of the battery is obtained based on a voltage of the battery before stopping the charging and a voltage of the battery after stopping the charging, and the battery is charged based on the voltage drop. Through the embodiments of the disclosure, the battery can be charged based on the state of the battery. In particular, after the battery has aged, different charging measures are taken based on the degree of battery aging. In this way, the decline in the charging speed of the aging battery is slowed down, which alleviates the problem of gradually decreased charging speed.

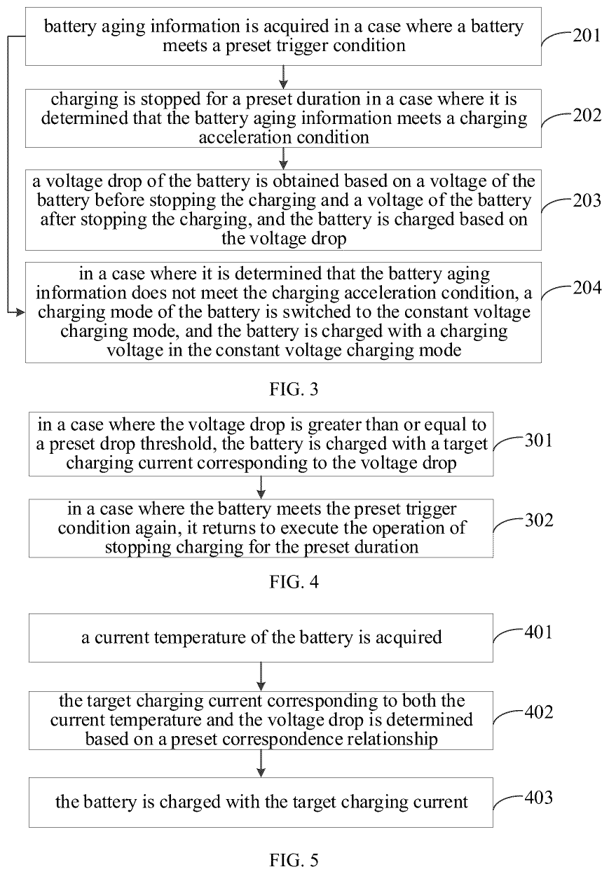

As illustrated in FIG. 3, after acquiring the battery aging information, some embodiments of the disclosure may further include operation 204.

At operation 204, in a case where it is determined that the battery aging information does not meet the charging acceleration condition, a charging mode of the battery is switched to the constant voltage charging mode, and the battery is charged with a charging voltage in the constant voltage charging mode.

After acquiring the battery aging information, it is determined whether the battery aging information meets the charging acceleration condition. When the battery aging information does not meet the charging acceleration condition, it indicates that the aging degree of the battery does not reach a preset aging degree. In this case, the battery may be charged in an original manner, that is, the charging mode of the battery is switched to the constant voltage charging mode in which the battery is charged with a constant charging voltage.

In the above embodiments, when it is determined that the battery aging information does not meet the charging acceleration condition, the charging mode of the battery is switched to the constant voltage charging mode, and the battery is charged with the charging voltage in the constant voltage charging mode. In the embodiments of the disclosure, the battery is charged using the original charging manner when the battery is not aged, which can reduce the decision-making processing, thereby saving energy consumption.

As illustrated in FIG. 4, an implementation related to the operation of “charging the battery based on the voltage drop” in the above embodiments is provided, which may include operations 301 and 302.

At operation 301, in a case where the voltage drop is greater than or equal to a preset drop threshold, the battery is charged with a target charging current corresponding to the voltage drop.

Specifically, the preset drop threshold may be defined as a drop voltage of a battery at a preset aging degree that is determined based on extensive experimental data. For example, the drop voltage is determined, based on experimental data, as X when the state of health of the battery falls below 50%, and the drop voltage X is taken as the preset drop threshold.

After acquiring the voltage drop, the voltage drop is compared with the preset drop threshold. When the voltage drop is greater than or equal to the preset drop threshold, it indicates that the aging degree of the battery reaches the preset aging degree, the constant current charging mode is maintained, and the battery is charged with the target charging current corresponding to the voltage drop.

It can be understood that, if the battery reaches the preset aging degree, the battery is still charged in the constant-current charging mode instead of switching to the constant-voltage charging mode. In this way, the duration of constant current charging may be prolonged, and the duration of constant voltage charging may be reduced, thereby slowing down the decline in the charging speed of the aging battery, and improving the user's charging experience.

At operation 302, in a case where the battery meets the preset trigger condition again, it returns to execute the operation of stopping the charging for the preset duration.

The battery is charged with the target charging current corresponding to the voltage drop, and the state of the battery is monitored during the charging. When the battery meets the preset trigger condition again, the charging is stopped again for the preset duration. Then, the voltage drop is again obtained based on a voltage of the battery before stopping the charging and a voltage of the battery after stopping the charging, and the battery is charged based on this voltage drop.

For example, when the battery is charged with the target charging current, and the battery voltage again reaches 9.0V, the charging is not immediately switched to the constant voltage charging mode. Instead, the charging is stopped again for 20 seconds and the voltage drop is then obtained, and subsequent charging procedure is determined based on this voltage drop.

In the above embodiments, when the voltage drop is greater than or equal to the preset drop threshold, the battery is charged with the target charging current corresponding to the voltage drop; when the battery meets the preset trigger condition again, it returns to execute the operation of stopping the charging for the preset duration. The embodiments of the disclosure utilize the voltage drop, i.e., a charging float voltage, to more accurately indicate the battery aging state, so that a more accurate charging current is matched based on different magnitudes of the float voltage, thereby further maximizing the charging speed without compromising the battery life. Compared with conventional technologies that recharge during standard charging, the technical solution in the embodiments of the disclosure enables re-entering of the fast charging, which offers higher efficiency, less heat generation, faster charging speed, and greater user benefits.

Based on the above embodiments, the operation of “charging the battery based on the voltage drop” may further include: in a case where the voltage drop is less than the preset drop threshold, switching a charging mode of the battery to the constant voltage charging mode, and charging the battery with a charging voltage in the constant voltage charging mode.

After obtaining the voltage drop, the voltage drop is compared with the preset drop threshold. When the voltage drop is less than the preset drop threshold, it indicates that the battery has not reached the preset aging degree, the charging mode of the battery is then switched to the constant voltage charging mode, and the battery is charged with the charging voltage in the constant voltage charging mode.

In the above embodiments, the charging float voltage may be used to more accurately indicate the battery aging state, and the battery is charged using the original charging manner when the battery is not aged, which can reduce the decision-making processing, thereby saving energy consumption.

As illustrated in FIG. 5, an implementation related to the operation of “charging the battery based on the voltage drop” in the above embodiments is provided, which may include operations 401, 402, and 403.

At operation 401, a current temperature of the battery is acquired.

The mobile terminal may acquire the current temperature of the battery through a temperature sensor provided on the battery.

At operation 402, the target charging current corresponding to both the current temperature and the voltage drop is determined based on a preset correspondence relationship.

Specifically, the correspondence relationship includes a relationship among temperature, voltage, and charging current.

After acquiring the current temperature of the battery, the target charging current corresponding to both the current temperature and the voltage drop may be determined based on the correspondence relationship.

Taking the correspondence relationship including a current relationship table as an example for description, the current relationship table may include multiple temperature ranges, each temperature range corresponds to multiple voltage ranges, and individual voltage ranges correspond to different charging currents. First, a target temperature range corresponding to the current temperature of the battery is found in the current relationship table, then a target voltage range corresponding to the voltage drop is found among the multiple voltage ranges corresponding to the target temperature range, and then the charging current corresponding to the target voltage range is determined as the target charging current.

For example, the current relationship table includes temperature ranges of −10° C.-0° C., 0° C.-5° C., 5° C.-10° C., 10° C.-18° C., 18° C.-35° C., 35° C.-45° C., and 45° C.-55° C., each temperature range corresponds to two voltage ranges of 0.1V-0.3V and 0.3V-0.5V, and individual voltage ranges correspond to different charging currents. When the current temperature of the battery is 20° C. and the voltage drop is 0.2V, the target temperature range corresponding to 20° C. may be determined as 18° C.-35° C. in the current relationship table, then the target voltage range corresponding to 0.2V is found as 0.1V-0.3V among the voltage ranges corresponding to the target temperature range, and then the charging current Ix corresponding to the target voltage range is determined as the target charging current.

It is notable that the form of the correspondence relationship is not limited to the above description, the implementation of determining the charging current based on the correspondence relationship is also not limited to the above description, and these may be set according to actual conditions.

At operation 403, the battery is charged with the target charging current.

After determining the target charging current, the battery is charged with the constant target charging current. It is notable that the target charging current is less than a charging current used before the battery meets the preset trigger condition. For example, when the battery is charged with a constant current of 1500 mA before meeting the preset trigger condition, the target charging current needs to be less than 1500 mA.

It can be understood that, if the battery is charged again using the charging current used before the preset trigger condition is met, the battery would soon meet the preset trigger condition again. However, if the battery is charged with a smaller target charging current, it can prolong the duration of the constant current charging, shorten the duration of the constant voltage charging, thereby improving the charging speed.

In the above embodiments, the current temperature of the battery is acquired, the target charging current corresponding to both the current temperature and the voltage drop is determined based on the preset correspondence relationship, and the battery is charged with the target charging current. The embodiments of the disclosure enable a more accurate charging current corresponding to the battery aging degree to be quickly matched based on the preset correspondence relationship and the voltage drop, thereby maximizing the charging speed without reducing the battery life.

In some embodiments, the battery aging information includes the charge-discharge cycle number of the battery. Based on such battery aging information, the embodiments of the disclosure may further include: in a case where the charge-discharge cycle number of the battery is greater than or equal to a preset cycle number threshold, determining that the battery aging information meets the charging acceleration condition; in a case where the charge-discharge cycle number of the battery is less than the preset cycle number threshold, determining that the battery aging information does not meet the charging acceleration condition.

In practice, the state of health of the battery may be defined by a capacity, an electric quantity, an internal resistance, a charge-discharge cycle number, a peak power, etc. Taking the state of heath of the battery including the charge-discharge cycle number as an example, the charge-discharge cycle number may be compared with a preset cycle number threshold to determine whether the battery aging information meets the charging acceleration condition. When the charge-discharge cycle number is greater than or equal to the preset cycle number threshold, it indicates that the battery has aged, and it is determined that the battery aging information meets the charging acceleration condition. When the charge-discharge cycle number is less than the preset cycle number threshold, it indicates that the battery has not aged, and it is determined that the battery aging information does not meet the charging acceleration condition.

In some embodiments, the implementation of determining the charge-discharge cycle number may include: calculating, based on an ampere-hour integration method (i.e., the coulomb counting method), a cumulative charging capacity and a cumulative discharging capacity of the battery; obtaining a total capacity by summing the cumulative charging capacity and the cumulative discharging capacity; and calculating a ratio of the total capacity to twice a nominal capacity, as the charge-discharge cycle number.

In the above embodiments, in a case where the charge-discharge cycle number of the battery is greater than or equal to the preset cycle number threshold, it is determined that the battery aging information meets the charging acceleration condition; in a case where the charge-discharge cycle number of the battery is less than the preset cycle number threshold, it is determined that the battery aging information does not meet the charging acceleration condition. In the embodiments of the disclosure, the charge-discharge cycle number is used to determine the aging degree of the battery, which helps to quickly have a general view of the state of the battery. This provides a basis for determining whether to implement charging acceleration measures subsequently, thereby improving the charging speed.

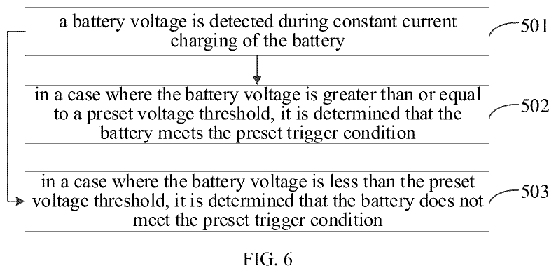

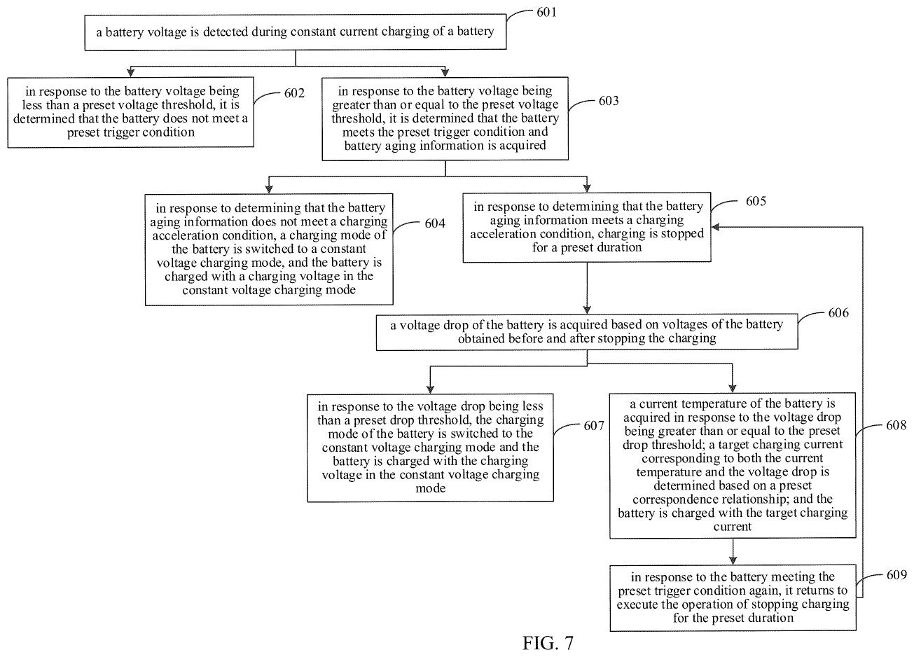

In some embodiments, as illustrated in FIG. 6, the operation of determining whether the battery meets the preset trigger condition may further include operations 501, 502, and 503.

At operation 501, a battery voltage is detected during constant current charging of the battery.

The battery may be charged based on the charging curve, such as the charging curve in Table 1 according to the above embodiments. During the constant current charging of the battery, the battery voltage is detected to determine whether the battery meets the preset trigger condition.

At operation 502, in a case where the battery voltage is greater than or equal to a preset voltage threshold, it is determined that the battery meets the preset trigger condition.

Based on the above charging curve, when the battery voltage is greater than or equal to the preset voltage threshold, it indicates the battery is appropriate to be switched from the constant current charging mode to the constant voltage charging mode. As such, it is determined that the battery meets the preset trigger condition. For example, when the current temperature of the battery is within −10° C.-0° C., the preset voltage threshold is 9.0V; in this case, when the detected battery voltage is greater than or equal to 9.0V, it is determined that the battery meets the preset trigger condition. For another example, when the current temperature of the battery is within 0° C.-5° C., the preset voltage threshold is 9.1V; in this case, when the detected battery voltage is greater than or equal to 9.1V, it is determined that the battery meets the preset trigger condition. In other words, before determining whether the battery meets the preset trigger condition, a current temperature of the battery is acquired, and a temperature range to which the current temperature belongs is determined; and the preset voltage threshold corresponding to the temperature range is determined, where different temperature ranges corresponding to different preset voltage thresholds.

At operation 503, in a case where the battery voltage is less than the preset voltage threshold, it is determined that the battery does not meet the preset trigger condition.

When the battery voltage is less than the preset voltage threshold, it indicates that the battery still requires the constant current charging, and it is determined that the battery does not meet the preset trigger condition. For example, when the current temperature of the battery is within −10° C.-0° C., the preset voltage threshold is 9.0V; in this case, when the detected battery voltage is less than 9.0V, it is determined that the battery does not meet the preset trigger condition.

In the above embodiment, the battery voltage is detected during the constant current charging of the battery; it is determined that the battery meets the preset trigger condition when the battery voltage is greater than or equal to the preset voltage threshold; it is determined that the battery does not meet the preset trigger condition when the battery voltage is less than the preset voltage threshold. In the embodiments of the disclosure, it is determined whether to switch the charging mode based on the battery voltage, which better aligns with the charging state of the battery, thereby achieving an optimized battery charging and further improving the user's charging experience.

As illustrated in FIG. 7, some embodiments provide a charging method. Taking the method applied to the mobile terminal in FIG. 1 as an example, the method includes operations 601 to 609.

At operation 601, a battery voltage is detected during constant current charging of a battery.

At operation 602, in a case where the battery voltage is less than a preset voltage threshold, it is determined that the battery does not meet a preset trigger condition.

At operation 603, in a case where the battery voltage is greater than or equal to the preset voltage threshold, it is determined that the battery meets the preset trigger condition and battery aging information is acquired.

At operation 604, in a case where it is determined that the battery aging information does not meet a charging acceleration condition, a charging mode of the battery is switched to a constant voltage charging mode, and the battery is charged with a charging voltage in the constant voltage charging mode.

At operation 605, charging is stopped for a preset duration, in a case where it is determined that the battery aging information meets the charging acceleration condition.

At operation 606, a voltage drop of the battery is obtained based on a voltage of the battery before stopping the charging and a voltage of the battery after stopping the charging.

At operation 607, in a case where the voltage drop is less than a preset drop threshold, the charging mode of the battery is switched to the constant voltage charging mode and the battery is charged with the charging voltage in the constant voltage charging mode.

At operation 608, in a case where the voltage drop is greater than or equal to the preset drop threshold, a current temperature of the battery is acquired, a target charging current corresponding to both the current temperature and the voltage drop is determined based on a preset correspondence relationship, and the battery is charged with the target charging current.

Specifically, the target charging current is less than a charging current used before the battery meets the preset trigger condition.

At operation 609, in a case where the battery meets the preset trigger condition again, it returns to execute the operation of stopping the charging for the preset duration.

In the above embodiments, whether to switch the charging mode is determined based on the battery voltage and the preset voltage threshold, which better aligns with the charging state of the battery, thereby achieving an optimized battery charging. In addition, the battery aging information and the charging float voltage may be used to more accurately indicate the battery aging state, so that a more precise charging current is matched based on different magnitudes of the float voltage, thereby further maximizing the charging speed without compromising the battery life. Compared with conventional technologies that recharge during standard charging, the technical solution in the embodiments of the disclosure enables re-entering of fast charging, which offers higher efficiency, less heat generation, faster charging speed, and greater user benefits.

It is understandable that, the operations in the flowchart of the above embodiments are displayed in sequence as indicated by the arrows, but these operations are not necessarily executed in the order indicated by the arrows. Unless otherwise specified herein, there is no strict order limitation for the execution of these operations, and these operations may be executed in other orders. In addition, at least part of the operations in the flowchart of the above embodiments may include multiple sub-operations or multiple stages. These sub-operations or stages are not necessarily executed at the same time, but may be executed at different times. The execution order of these sub-operations or stages is not necessarily sequential, but may be executed in turn or alternately with other operations or at least part of the sub-operations or stages of other operations.

Based on the same inventive concept, the embodiments of the disclosure further provide a charging apparatus for implementing the above-mentioned charging method. The implementation scheme for solving problems provided by the apparatus is similar to the implementation scheme recited in the above-mentioned method. Therefore, for the specific limitations in the embodiments of the charging apparatus provided below may refer to the limitations for the charging method described above, and will not be repeated here.

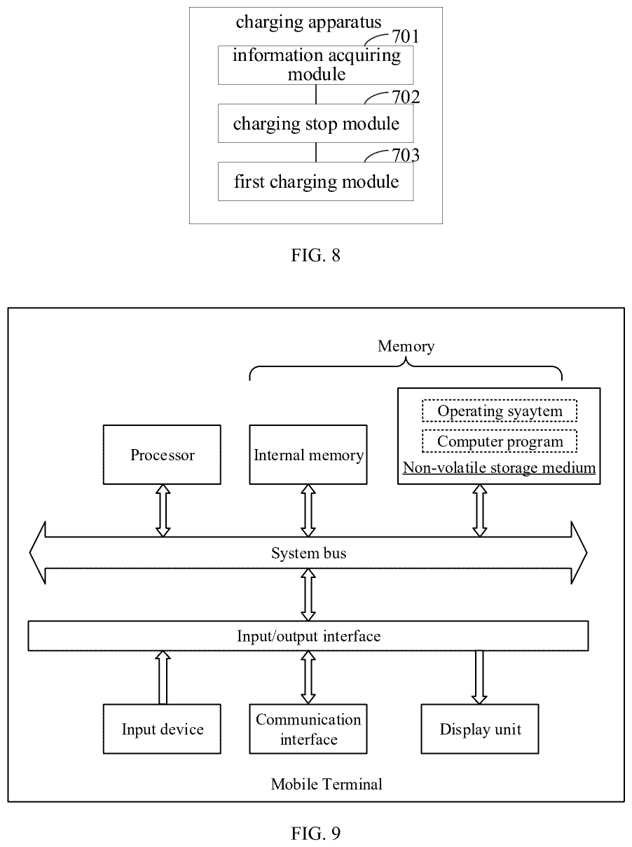

As illustrated in FIG. 8, some embodiments provide a charging apparatus. The charging apparatus includes an information acquiring module 701, a charging stop module 702, and a first charging module 703.

The information acquiring module 701 is configured to acquire battery aging information when a battery meets a preset trigger condition, where the preset trigger condition includes a trigger condition for switching from a constant current charging mode to a constant voltage charging mode.

The charging stop module 702 is configured to stop charging for a preset duration when it is determined that the battery aging information meets a charging acceleration condition.

The first charging module 703 is configured to obtain a voltage drop of the battery based on a voltage of the battery before stopping the charging and a voltage of the battery after stopping the charging, and charge the battery based on the voltage drop.

In some embodiments, the first charging module 703 is specifically configured to: charge the battery with a target charging current corresponding to the voltage drop when the voltage drop is greater than or equal to a preset drop threshold; and return to execute the operation of stopping the charging for the preset duration when the battery meets the preset trigger condition again.

In some embodiments, the first charging module 703 is specifically configured to: acquire a current temperature of the battery; determine, based on a preset correspondence relationship, the target charging current corresponding to both the current temperature and the voltage drop, where the correspondence relationship includes a relationship among temperature, voltage, and charging current; and charge the battery with the target charging current, where the target charging current is less than a charging current used before the battery meets the preset trigger condition.

In some embodiments, the first charging module 703 is specifically configured to: when the voltage drop is less than the preset drop threshold, switch a charging mode of the battery to the constant voltage charging mode, and charge the battery with a charging voltage in the constant voltage charging mode.

In some embodiments, the apparatus further includes a second charging module.

The second charging module is configured to: when it is determined that the battery aging information does not meet the charging acceleration condition, switch a charging mode of the battery to the constant voltage charging mode, and charge the battery with a charging voltage in the constant voltage charging mode.

In some embodiments, the battery aging information includes the charge-discharge cycle number of the battery.

In some embodiments, the apparatus further includes a first aging determining module and a second aging determining module.

The first aging determining module is configured to: when the charge-discharge cycle number of the battery is greater than or equal to a preset cycle number threshold, determine that the battery aging information meets the charging acceleration condition.

The second aging determining module is configured to: when the charge-discharge cycle number of the battery is less than the preset cycle number threshold, determine that the battery aging information does not meet the charging acceleration condition.

In some embodiments, the apparatus further includes a voltage detecting module, a first trigger determining module and a second trigger determining module.

The voltage detecting module is configured to detect a battery voltage during constant current charging of the battery.

The first trigger determining module is configured to: when the battery voltage is greater than or equal to a preset voltage threshold, determining that the battery meets the preset trigger condition.

The second trigger determining module is configured to: when the battery voltage is less than the preset voltage threshold, determining that the battery does not meet the preset trigger condition.

The various modules in the charging apparatus may be implemented as a whole or in part by software, hardware, and combinations thereof. The above-mentioned various modules may be embedded in or independent of the processor of the computer device in the form of hardware, or may be stored in the memory of the computer device in the form of software, so as to be recalled by the processor to perform the operation corresponding to the above-mentioned various modules.

In some embodiments, a mobile terminal is provided, and its internal structure diagram may be as illustrated in FIG. 9. The mobile terminal includes a processor, a memory, an input/output interface, a communication interface, a display unit, and an input device. Specifically, the processor, the memory, and the input/output interface are connected through a system bus, and the communication interface, the display unit, and the input device are connected to the system bus through the input/output interface. The processor of the mobile terminal is configured to provide computing and control capabilities. The memory of the mobile terminal includes a non-volatile storage medium and an internal memory. The non-volatile storage medium stores an operating system and a computer program. The internal memory provides an environment for operations of the operating system and the computer program in the non-volatile storage medium. The input/output interface of the mobile terminal is configured to exchange information between the processor and an external device. The communication interface of the mobile terminal is configured to communicate with an external terminal in a wired manner or a wireless manner, and the wireless manner may be realized through WIFI, a mobile cellular network, near field communication (NFC), or other technologies. The computer program is executed by the processor to implement the charging method. The display unit of the mobile terminal is configured to present visual images and may be a display screen, a projection device, or a virtual reality imaging device. The display screen may be a liquid crystal display screen or an electronic ink display screen. The input device of the mobile terminal may be a touch layer covered on the display screen, or a button, a trackball, or a touch pad provided on the housing of the mobile terminal.

It should be understood by a person skilled in the art that the structure as illustrated in FIG. 9 is only a part of the structure related to the solution of the disclosure, and does not constitute a limitation on the mobile terminal to which the solution of the disclosure is applied. The mobile terminal may include more or fewer components than those as illustrated in the drawings, or combine some components, or have different component arrangements.

The embodiments of the disclosure further provide a computer-readable storage medium. One or more non-volatile computer-readable storage media include computer-executable instructions stored thereon. The computer-executable instructions, when being executed by one or more processors, cause the processors to execute the operations of the charging method in the above embodiments.

The embodiments of the disclosure further provides a computer program product including instructions that, when executed by a computer, causes the computer to execute the charging method in the above embodiments.

It is notable that all of user information (including, but not limited to, user device information, user personal information, etc.) and data (including, but not limited to, data configured for analysis, stored data, displayed data, etc.) involved in the disclosure are authorized by the user or fully authorized by all parties. In addition, collection, use, and processing of relevant data need to comply with the relevant laws, regulations, and standards of relevant countries and regions.

A person skilled in the art can understand that all or part of the processes in the above method embodiments may be implemented by instructing relevant hardware through a computer program. The computer program may be stored in a non-volatile computer-readable storage medium. When the computer program is executed, the process of any of the above embodiments can be realized. Any reference to a memory, a database, or other media provided in the various embodiments of the disclosure may include at least one of a non-volatile memory and a volatile memory. The non-volatile memory may include a read-only memory (ROM), a tape, a floppy disk, a flash memory, an optical memory, a high-density embedded non-volatile memory, a resistive random access memory (ReRAM), a magnetoresistive random access memory (MRAM), a ferroelectric random access memory (FRAM), a phase change memory (PCM), a graphene memory, etc. The volatile memory may include a random access memory (RAM) or an external cache memory. For illustration but not limitation, the RAM is available in various forms, such as a static random access memory (SRAM), or a dynamic random access memory (DRAM). The database provided in the embodiments of the disclosure may include at least one of a relational database and a non-relational database. The non-relational database may include a blockchain-based distributed database, etc., which is not limited herein. The processor provided in the various embodiments of the disclosure may be a general processor, a central processor, a graphics processor, a digital signal processor, a programmable logic controller, a quantum computing-based data processing logic controller, etc., which is not limited herein.

The various technical features of the above-described embodiments may be combined arbitrarily. To make the description concise, not all possible combinations of the various technical features in the embodiments are described. However, as long as there is no contradiction in the combination of these technical features, all combinations of these technical features should be considered to be within the scope of the specification.

The foregoing embodiments illustrates only several implementations of the disclosure and are described in detail, which however are not to be construed as a limitation to the scope of the disclosure. It is notable that, for a person skilled in the art, several modifications and improvements can be made without departing from the idea of the disclosure, and these all fall within the protection scope of this disclosure. Therefore, the protection scope of the disclosure should be subject to the appended claims.

What is claimed is:

1. A charging method, comprising:
acquiring battery aging information in a case where a battery meets a preset trigger condition during a process of charging the battery in a constant current charging mode, wherein the preset trigger condition comprises a trigger condition for switching from the constant current charging mode to a constant voltage charging mode;
in a case where it is determined that the battery aging information meets a charging acceleration condition, stopping charging for a preset duration; and
acquiring a voltage drop of the battery based on a voltage of the battery before stopping the charging and a voltage of the battery after stopping the charging, and charging the battery based on the voltage drop.

2. The charging method as claimed in claim 1, wherein charging the battery based on the voltage drop, comprises:
in a case where the voltage drop is greater than or equal to a preset drop threshold, charging the battery with a target charging current corresponding to the voltage drop; and
in a case where the battery meets the preset trigger condition again, returning to execute the operation of stopping the charging for the preset duration.

3. The method as claimed in claim 2, wherein charging the battery with the target charging current corresponding to the voltage drop, comprises:
acquiring a current temperature of the battery;
determining, based on a preset correspondence relationship, the target charging current that corresponds to both the current temperature and the voltage drop, wherein the correspondence relationship comprises a relationship among temperature, voltage, and charging current; and
charging the battery with the target charging current, wherein the target charging current is less than a charging current used before the battery meets the preset trigger condition.

4. The method as claimed in claim 3, wherein the preset correspondence relationship comprises a current relationship table, the current relationship table comprises a plurality of temperature ranges, each of the plurality of temperature ranges corresponds to a plurality of voltage ranges, and each of the plurality of voltage ranges corresponds to a charging current.

5. The method as claimed in claim 4, wherein determining, based on the preset correspondence relationship, the target charging current that corresponds to both the current temperature and the voltage drop, comprises:
determining, from the plurality of temperature ranges in the current relationship table, a target temperature range in which the current temperature of the battery is located;
determining, from the plurality of voltage ranges corresponding to the target temperature range, a target voltage range in which the voltage drop is located; and
determining, as the target charging current, a charging current corresponding to the target voltage range in the current relationship table.

6. The method as claimed in claim 2, wherein charging the battery based on the voltage drop, further comprises:
in a case where the voltage drop is less than the preset drop threshold, switching a charging mode of the battery to the constant voltage charging mode, and charging the battery with a charging voltage in the constant voltage charging mode.

7. The method as claimed in claim 1, further comprising:
in a case where it is determined that the battery aging information does not meet the charging acceleration condition, switching a charging mode of the battery to the constant voltage charging mode, and charging the battery with a charging voltage in the constant voltage charging mode.

8. The method as claimed in claim 1, wherein the battery aging information comprises a charge-discharge cycle number of the battery.

9. The method as claimed in claim 8, further comprising:
in a case where the charge-discharge cycle number of the battery is greater than or equal to a preset cycle number threshold, determining that the battery aging information meets the charging acceleration condition;
in a case where the charge-discharge cycle number of the battery is less than the preset cycle number threshold, determining that the battery aging information does not meet the charging acceleration condition.

10. The method as claimed in claim 9, further comprising:
calculating, based on an ampere-hour integration method, a cumulative charging capacity and a cumulative discharging capacity of the battery;
obtaining a total capacity by summing the cumulative charging capacity and the cumulative discharging capacity; and
calculating a ratio of the total capacity to twice a nominal capacity, as the charge-discharge cycle number.

11. The method as claimed in claim 1, further comprising:
detecting a battery voltage during constant current charging of the battery; and
in a case where the battery voltage is greater than or equal to a preset voltage threshold, determining that the battery meets the preset trigger condition;
in a case where the battery voltage is less than the preset voltage threshold, determining that the battery does not meet the preset trigger condition.

12. The method as claimed in claim 11, further comprising:
acquiring a current temperature of the battery, and determining a temperature range in which the current temperature is located; and
determining the preset voltage threshold corresponding to the temperature range, wherein different temperature ranges corresponding to different preset voltage thresholds.

13. The method as claimed in claim 1, further comprising:
detecting a battery capacity during constant current charging of the battery; and
in a case where the battery capacity is greater than or equal to a preset capacity threshold, determining that the battery meets the preset trigger condition;
in a case where the battery capacity is less than the preset capacity threshold, determining that the battery does not meet the preset trigger condition.

14. The method as claimed in claim 1, wherein the battery aging information comprises a health of state of the battery, and the method further comprises:
calculating an internal resistance of the battery, based on a measured voltage, a measured current, and a measured temperature of the battery; and
calculating the health of state of the battery, based on the calculated internal resistance of the battery and a pre-established correspondence relationship between health of states and internal resistances of the battery.

15. The method as claimed in claim 14, wherein the charging acceleration condition comprises that the battery aging information indicates that an aging degree of the battery reaches a preset aging degree, or the health of state of the battery is lower than a preset health degree threshold.

16. A mobile terminal, comprising a battery a memory and a processor, wherein a computer program is stored in the memory, and the computer program, when being executed by the processor, cause the processor to:
acquire, during a process of charging the battery in a constant current charging mode, battery aging information when the battery meets a trigger condition for switching from the constant current charging mode to a constant voltage charging mode; and
when it is determined that the battery aging information meets a charging acceleration condition, stop charging for a preset duration, acquire a voltage drop of the battery based on a voltage of the battery before stopping the charging and a voltage of the battery after stopping the charging, and charge the battery based on the voltage drop.

17. The mobile terminal as claimed in claim 16, wherein the computer program, when being executed by the processor, further cause the processor to:
when the voltage drop is greater than or equal to a preset drop threshold, charge the battery with a target charging current corresponding to the voltage drop in the constant current charging mode; and
when the battery meets the preset trigger condition again, returning to execute the operation of stopping the charging for the preset duration.

18. The mobile terminal as claimed in claim 17, wherein the computer program, when being executed by the processor, further cause the processor to:
acquire a current temperature of the battery;
determine, based on a preset correspondence relationship, the target charging current that corresponds to both the current temperature and the voltage drop, wherein the correspondence relationship comprises a relationship among temperature, voltage, and charging current; and
charge the battery with the target charging current, wherein the target charging current is less than a charging current used before the battery meets the preset trigger condition.

19. The mobile terminal as claimed in claim 17, wherein the computer program, when being executed by the processor, further cause the processor to:
when the voltage drop is less than the preset drop threshold, switch a charging mode of the battery to the constant voltage charging mode, and charge the battery with a charging voltage in the constant voltage charging mode.

20. A non-transitory computer-readable storage medium having a computer program stored thereon, wherein the computer program, when being executed by a processor of a mobile terminal, causes the processor to execute a charging method comprising:
acquiring battery aging information in a case where a battery of the mobile terminal meets a preset trigger condition during a process of charging the battery in a constant current charging mode, wherein the preset trigger condition comprises a trigger condition for switching from the constant current charging mode to a constant voltage charging mode;
in a case where it is determined that the battery aging information meets a charging acceleration condition, stopping charging for a preset duration; and
acquiring a voltage drop of the battery based on a voltage of the battery before stopping the charging and a voltage of the battery after stopping the charging, and charging the battery based on the voltage drop.
